(19) United States
(12) Patent Application Publication
(10) Pub. No.: US 2011/0043218 A1
(43) Pub. Date: Feb. 24, 2011

(54) ANALYSIS METHOD AND ANALYSIS SYSTEM

(76) Inventors: Yet-Men Wang, Taipei City (TW); Ming-Shing Su, Banqiao City (TW); Kyle Da-Kai Chen, Kaohsiung City (TW)

Correspondence Address: PATTERSON & SHERIDAN, LLP - - - IPTEC, 3040 Post Oak Boulevard, Suite 1500, Houston, TX, 77056-6582, US

(21) Appl. No.: 12/859,021

(22) Filed: Aug. 18, 2010

(30) Foreign Application Priority Data
Aug. 18, 2009 (TW) 098127705

(51) Int. Cl. G01R 31/02

(52) U.S. Cl. 324/537

(57) ABSTRACT

The invention discloses an analysis method and an analysis system for analyzing an integrated circuit comprising a plurality of electronic components. The analysis method comprises steps of: performing a measurement or a simulation on an integrated circuit to obtain a time-domain waveform of an output signal of the integrated circuit; applying an time-frequency analysis to the time-domain waveform to obtain one or more frequency components; selecting a target frequency component from the one or more frequency components and identifying a point-in-time when an amplitude of the target frequency component changes; from the plurality of electronic components of the integrated circuit, identifying one or more target electronic components under an operating state at the point-in-time. The analysis system comprises a processing module and a memory module. The processing module analyzes the time-frequency information of an output signal of the integrated circuit according to the logical rules stored in the memory module.

### REFERENCE TO RELATED APPLICATION

This application claims the priority of Taiwanese Application No. 098127705, filed on Aug. 18, 2009.

### BACKGROUND

The present invention relates to an analysis method and an analysis system for analyzing an integrated circuit, and in particular relates to an analysis method and an analysis system used for testing and debugging an integrated circuit.

With the developments and advancements in the semiconductor and electronic industries, integrated circuits are widely used in a variety of computational applications, such as communications and signal processing. In today's sub-micron manufacturing processes, an integrated circuit typically contains millions of electronic components operating at incredibly high speeds. The electronic components in the integrated circuit communicate or exchange signals with other electronic components in the same integrated circuit or in another integrated circuit via interfaces such as internal wires or the input/output signal pins.

Signal errors may result from the resistance in the wires and the distance of the wires among the large number of electronic components in an integrated circuit. The integrated circuit may also be affected by the electrostatic discharge and/or the electromagnetic interference, as well as other factors, and hence can produce unexpected signal errors.

To ensure that the electronic components in an integrated circuit can operate and communicate correctly, and that the integrated circuit's output signals can fulfill the needs of the designers, typically extensive simulations and numerous test versions of the circuits need to be made in a trial-and-error process before a working integrated circuit can reach the production stage.

However, with today's technological complexity, output signals of a variety of high-frequency integrated circuits (such as those for telecommunications or radio frequency identification) are no longer just simple high-and-low signals, but a mixture of various components of different frequencies and wave-type signals. Without suitable signal analysis tools, it is very difficult for a designer to determine if the output signal waveforms satisfy the integrated circuit's design requirements.

Needless to say, for today's highly integrated Very-Large-Scale Integrations (or VLSIs), it is no longer an efficient designing or debugging method to manually determine from a circuit's output signals which portions of the components in the integrated circuit are causing such abnormal signals.

In order to solve the problems described above, the present invention provides an analysis method and an analysis system that can be used to improve the efficiency for the implementation of integrated circuit testing and debugging processes to solve the problems described above.

### DISCLOSURE OF THE INVENTION

One aspect of the present invention is to provide an analysis method that can be used for analyzing an integrated circuit comprising a plurality of electronic components.

According to an embodiment of the present invention, the analysis method comprises the following steps:

a) Identifying a time-domain waveform of an output signal by measuring or simulating an integrated circuit comprising a plurality of electronic components;
b) Identifying one or more frequency components of said output signal by performing a time-frequency analysis on said time-domain waveform;
c) Selecting a target frequency component from said one or more frequency components, and identifying a point-in-time when a change in an amplitude of said target frequency component occurs;
d) Identify one or more target electronic components from said plurality of electronic components, wherein an operating state of said one or more target electronic components occurs at said point-in-time.

According to another embodiment of the present invention, the analysis method comprises the following steps:

a) Identifying a time-domain waveform of an output signal by measuring or simulating an integrated circuit comprising a plurality of electronic components;
b) Identifying a plurality of frequency components of said output signal from said time-domain waveform;
c) Selecting a target frequency component from said plurality of frequency components;
d) Identifying a relationship between amplitude of said target frequency component and a time axis by performing a time-frequency analysis;
e) Identifying a point-in-time when a change in said amplitude occurs from a result of said time-frequency analysis;
f) Identifying one or more target electronic components from said plurality of electronic components, wherein an operating state of said one or more target electronic components occurs at said point-in-time.

In addition, by incorporating the analysis method above into logical rules, a rule-based analysis system (for example, an expert system installed on a computer) can apply such logical rules to automatically identify the target components of which an operating state occurs at the point-in-time when an amplitude change occurs in the target frequency components. Another aspect of the present invention is to provide such an analysis system for analyzing an integrated circuit.

According to another embodiment of the present invention, an analysis system comprises a memory module and a processing module. The memory module and the processing module are electrically connected. The memory module stores a first logical rule and a second logical rule, wherein the first logical rule defines a change in amplitude of a frequency component, and the second logical rule defines an operating state in an electronic component. The processing module analyzes the frequency components in the output signal of the integrated circuit and identifies a point-in-time when a change in amplitude in a target frequency component occurs. The processing module then identifies the target electronic component by determining which electronic component's operating state in question occurs at the point-in-time when the amplitude change occurs in the target frequency component.

Compared with the prior art, the present invention's analysis method and analysis system perform time-frequency analysis on an output signal of the integrated circuit to identify a target frequency component that may be associated with an abnormality of the integrated circuit. Then, from the results in the time-frequency analysis, the analysis method and the analysis system identify the point-in-time when amplitude of the target frequency components occurs. From such point-in-time, the analysis method and the analysis system identify the electronic component by determining which electronic component's operating state in question (e.g., signal switching) occurs at the point-in-time. Through the analysis method and the analysis system, a designer can quickly focus on the portion of electronic components in an integrated circuit that may be generating the abnormalities, and hence the efficiency of the design or testing process can be improved. In addition, the waste of time and resources in simulating or prototyping an integrated circuit in a drawn-out trial-and-error process only to find out the output signal of the integrated circuit is not up to the specification can be avoided.

### BRIEF EXPLANATION OF FIGURES

FIG. 1 shows a flowchart of an analysis method in an embodiment of the present invention;

FIG. 2 shows a time-domain waveform of an integrated circuit in an embodiment of the present invention;

FIG. 3 shows a transformed waveform of an integrated circuit in an embodiment of the present invention;

FIG. 4 shows a time-frequency analysis of an integrated circuit in an embodiment of the present invention.

FIG. 5 shows a different embodiment of the present invention, which is an analysis system.

### DETAILED DESCRIPTION OF INVENTION

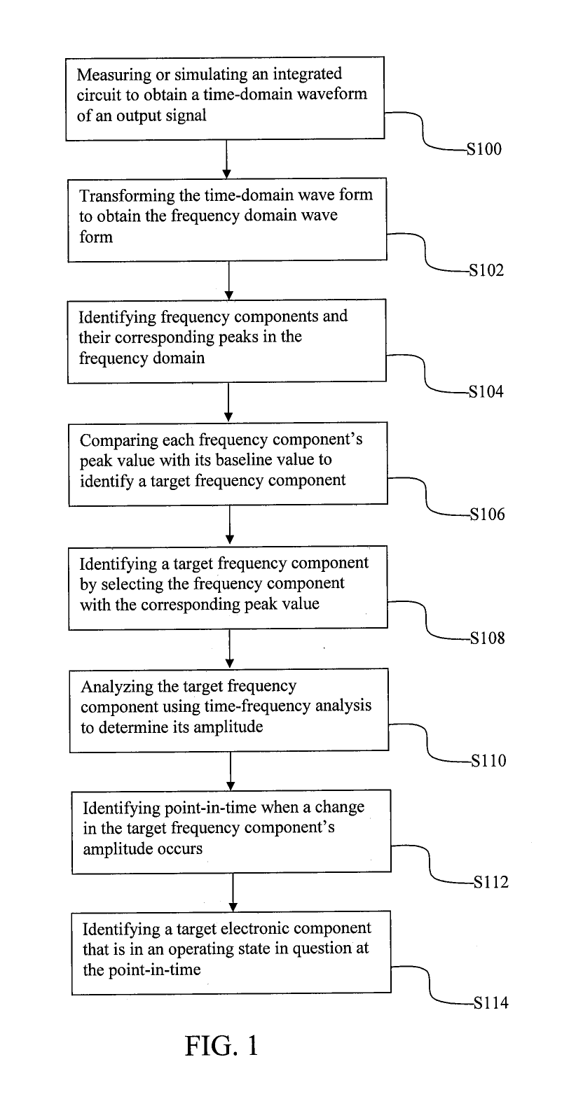

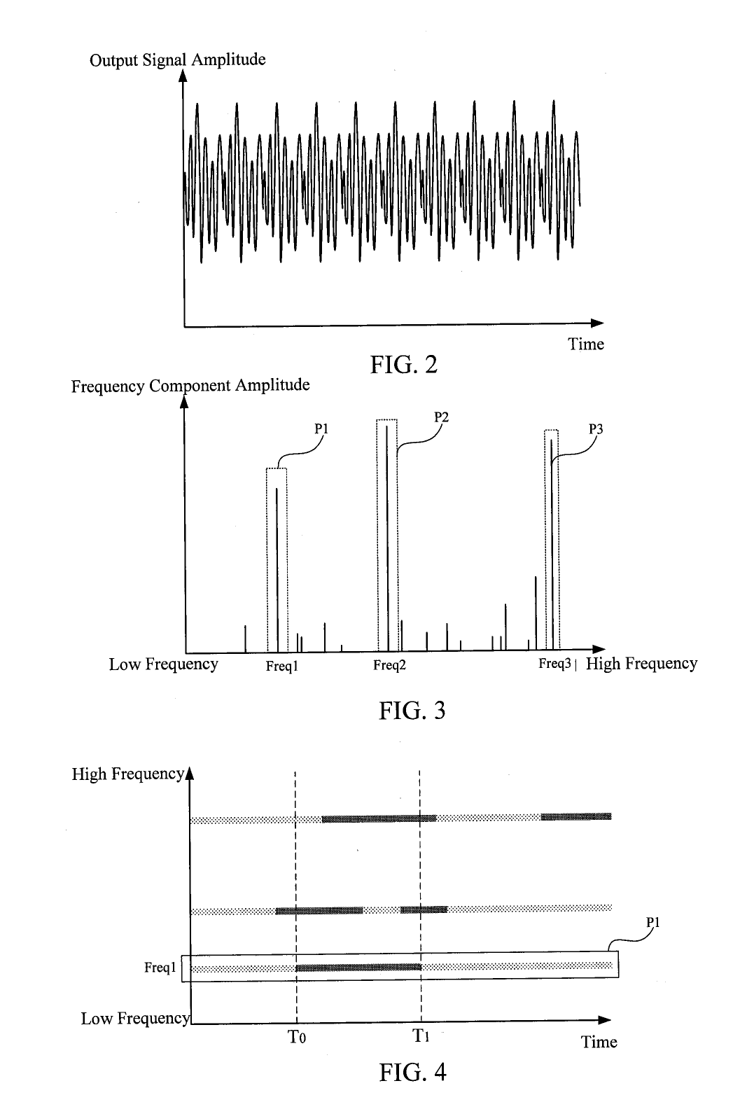

Refer to FIG. 1, which shows a flowchart of an analysis method in an embodiment of the present invention. The analysis method can be broadly applied in the testing and debugging applications in various integrated circuits, especially for VLSIs in high frequency or telecommunication applications. In this embodiment, the integrated circuit contains a plurality of electronic components. In actual applications, for example, a high-performance microprocessor can contain seven to eight million electronic components. As shown in FIG. 1, step S100 of the analysis method in this embodiment measures or simulates an output signal of an integrated circuit. In actual applications, for example, SPICE software can be used to generate input signal for the integrated circuit, and then the output signal of the integrated circuit can be measured or simulated, and a time-domain waveform of the output signal can be obtained, as seen in, e.g., FIG. 2, which shows a time-domain waveform of an integrated circuit in an embodiment of the present invention. As seen in FIG. 2, the output signal may consist of many waves of different frequencies; that is, the output signal contains a plurality of frequency components.

Step S102 of the analysis method in this embodiment transforms the time-domain waveform of the output signal as seen in, e.g., FIG. 2, and obtain the frequency-domain waveform of the output signal, as seen in, e.g., FIG. 3, which shows a transformed waveform of the output signal of an integrated circuit in an embodiment of the present invention. The transforming method may include without limitation Fourier Transform (FT), or other time-frequency transforms or computations.

Then, step S104 of the analysis method in this embodiment identifies from the waveform in FIG. 3 a plurality of frequency components. As shown in FIG. 3, frequency waveforms include a plurality of peaks, P1, P2 and P3. These three peaks, P1, P2 and P3 correspond to three different frequency components, Freq1, Freq2 and Freq 3.

Then, the analysis method of this embodiment identifies a target frequency component. Steps S106 and S108 can accomplish the selection of the target frequency component. First, step S106 compares peaks P1, P2 and P3 with the baseline values, and identifies from the peaks P1, P2 and P3 the peak of the target frequency component. In this embodiment, for example, because the amplitude of peak P1 is smaller than the baseline value, the frequency component of P1 will be selected as the target frequency. However, different peaks P1, P2 and P3 may have different baseline values in actual applications, and the selection is not limited to a comparison of the amplitude and the baseline value.

Then, step S108 accordingly selects Freq1 as the target frequency because in this embodiment Freq1 corresponds to peak P1.

Then, step S110 analyzes the waveform of the output signal by performing a time-frequency analysis, which analyzes changes over time in the amplitude of each frequency component in the output signal, as in, e.g., FIG. 4, which shows a time-frequency analysis of an integrated circuit in an embodiment of the present invention. In actual applications, the time-frequency analysis may be based upon a Hilbert-Huang Transform, of which the computation may include Empirical Mode Decomposition (EMD) or Hilbert Transform (HT). The time-frequency analysis is not limited to the Hilbert-Huang Transform, however. Short-Term Fourier Transform or Wavelet Transform may also be used.

In this embodiment, step S110 analyzes the amplitude of the target frequency component Freq1. As shown in FIG. 4, which is a chart of time-frequency analysis, the changes over time in the amplitude of each frequency component can be shown. As in FIG. 4, the magnitude of the amplitude can be shown as the density of a region, i.e., high density indicates high amplitude, while low density indicates low amplitude. The method of showing the magnitude is not limited to densities. In another embodiment, changes over time in the magnitude of a frequency component's amplitude may be shown as different colors, or different heights in a three-dimensional figure.

Then, from the time-frequency analysis, step S112 identifies the point-in-time when the change in the amplitude of the target frequency component occurs. In this embodiment, when the target frequency Freq1's amplitude changes from low to high, such point-in-time when such change occurs, T0, can be identified. In actual applications, the change in a target frequency's amplitude may be associated with abnormalities such as electro-static discharge (ESD) current, electro-magnetic interference (EMI) or abnormal noise in the circuit. These abnormalities may occur when an electronic component is in an operating state in question, such as signal switching.

The point-in-time identified in step S112 is not limited to the rising edge (T0) when the amplitude changes from low to high. In another embodiment, when the target frequency's amplitude changes from high to low, a different point-in-time, or the falling edge T1 as shown in FIG. 4, can also be identified. The present invention can also use T1 for analysis, or can use both T0 and T1 for analysis.

Then, in one embodiment, step S114 identifies a target electronic component from the plurality of electronic components in the integrated circuit by determining which electronic component's operating state in question (e.g., signal switching) at the point-in-time. In particular, step S114 can be implemented as follows:

(1) Obtaining the output signal of each of the plurality of electronic components by measuring or simulating them;
(2) Based upon the output signal of each electronic component, determining if an operating state in question of an electronic component occurs at the point-in-time;
(3) If an operating state in question of an electronic component occurs in (2), the electronic component under the operating state in question at the point-in-time is identified as the target electronic component.

In another embodiment, the target electronic component can be identified in step S114 by performing time-frequency analysis upon the plurality of electronic components as follows:

(1) Obtaining the output signal of each of the plurality of electronic components by measuring or simulating them;
(2) Performing time-frequency analysis upon each such output signal;
(3) Based upon the result of time-frequency analysis performed in (2), determine if an operating state in question of an electronic component occurs at the point-in-time;
(4) If an operating state in question of an electronic component occurs in (3), the electronic component under the operating state in question at the point-in-time is identified as the target electronic component.

Hence, step S114, by identifying the point-in-time when the change in the target frequency component's amplitude occurs, can help the designer or tester focus quicker on the electronic components that are also in an operating state in question (e.g., switching on and/or off, or switching signals) at such point-in-time because they are possibly causing the abnormalities. In turn, the efficiency of the design or testing process can be improved.

In summary, the present invention's analysis method and analysis system perform time-frequency analysis on output signals to identify the point-in-time when a target frequency component's change in its amplitude occurs. From such point-in-time, the analysis method and analysis system identify the target electronic component by finding out which electronic component's operating state in question (e.g., signal switching) occurs at the point-in-time. Through the analysis method and analysis system, a designer can quickly focus on the portion of possibly abnormal electronic components, and hence the efficiency of the design or testing process can be improved. In addition, the waste of time and resources in repeatedly simulating or prototyping an integrated circuit can be avoided.

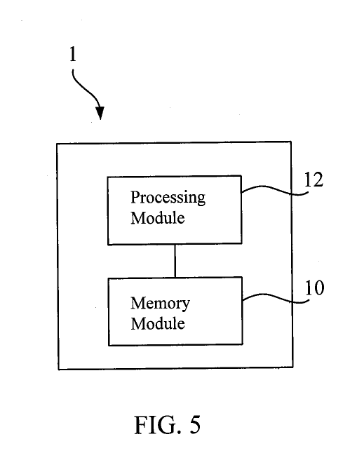

Additionally, in another embodiment of the present invention, an analysis system implementing the above analysis method comprises a memory module and a processing module, as shown in FIG. 5. In the analysis system 1, the memory module 10 and the processing module 12 are electrically connected. The memory module 10 stores a first logical rule and a second logical rule, wherein the first logical rule defines a change in amplitude of a frequency component, and the second logical rule defines an operating state in an electronic component. The processing module 12 analyzes the frequency components in the output signal of the integrated circuit and identifies a point-in-time when a change in amplitude of a target frequency component occurs based upon the first logical rule stored in the memory module 10. The processing module 12 then identifies the target electronic component by determining which electronic component's operating state in question as defined in the second logical rule stored in the memory module 10 occurs at the point-in-time when the amplitude change occurs in the target frequency component.

In this embodiment, the first logical rule and the second logical rules are based upon the analysis method described previously in FIGS. 1-4. That is, the analysis system 1 can be used to implement the analysis method described previously in FIGS. 1-4 by applying the first and the second logic rules to automatically identify the target component whose operating state in question occurs at the point-in-time when the amplitude of the target frequency component changes.

The invention claimed is as follows:

1. An analysis method comprising the following steps:
a) Measuring or simulating an integrated circuit comprising a plurality of electronic components to obtain an output signal;
b) Transforming said output signal using a time-frequency analysis to identify a frequency component;
c) Identify a point-in-time when a change in amplitude of said frequency component occurs;
d) Identify a target electronic component from said plurality of electronic components, wherein an operating state of said target electronic component occurs at said point-in-time.

2. The analysis method as in claim 1, wherein said time-frequency analysis is based on Hilbert-Huang Transform.

3. The analysis method as in claim 1, wherein said time-frequency analysis is based on Empirical Mode Decomposition.

4. The analysis method as in claim 1, wherein said time-frequency analysis is based on Hilbert Transform.

5. The analysis method as in claim 1, wherein said time-frequency analysis is based Short-Term Fourier Transform.

6. The analysis method as in claim 1, wherein said time-frequency analysis is based on Wavelet Transform.

7. An analysis system for analyzing an integrated circuit comprising a plurality of electronic components, the analysis system comprising:
a memory module storing a first logical rule and a second logical rule, wherein said first logical rule defines a manner in which an amplitude changes, and said second logical rule defines an operating state;
a processing module electrically connected with said memory module, wherein said processing module is capable of transforming an output signal of said integrated circuit using a time-frequency analysis to identify a frequency component, of identifying a point-in-time when said frequency component's amplitude changes in said manner as defined in said first logical rule, and of identifying a target electronic component from said plurality of electronic components that at said point-in-time is under said operating state as defined in said second logical rule.

8. The analysis system as in claim 7, wherein said time-frequency analysis is based on Hilbert-Huang Transform.

9. The analysis system as in claim 7, wherein said time-frequency analysis is based on Empirical Mode Decomposition.

10. The analysis system as in claim 7, wherein said time-frequency analysis is based on Hilbert Transform.

11. The analysis system as in claim 7, wherein said time-frequency analysis is based Short-Term Fourier Transform.
